(19) United States
(12) Patent Application Publication
(10) Pub. No.: US 2012/0049334 A1
(43) Pub. Date: Mar. 1, 2012

(54) Semiconductor Device and Method of Forming Leadframe as Vertical Interconnect Structure Between Stacked Semiconductor Die

(75) Inventors: Reza A. Pagaila, Singapore (SG); Yaojian Lin, Singapore (SG); Jun Mo Koo, Singapore (SG)

(73) Assignee: STATS CHIPPAC, LTD., Singapore (SG)

(21) Appl. No.: 12/870,681

(22) Filed: Aug. 27, 2010

(51) Int. Cl. H01L 23/495; H01L 21/56

(52) U.S. Cl. 257/666; 438/107; 257/E21.502; 257/E23.031

(57) ABSTRACT

A semiconductor device has a first semiconductor die mounted over a carrier. A leadframe has a plurality of conductive leads and first and second bodies extending from the opposite sides of the conductive leads. The leadframe is mounted to the carrier with the conductive lead disposed over the first semiconductor die and the bodies disposed around the first semiconductor die. An adhesive layer is deposited between the first semiconductor die and conductive leads. A second semiconductor die is mounted over the leadframe and electrically connected to the conductive leads. An encapsulant is deposited over the first semiconductor die. The carrier is removed. A first interconnect structure is formed over a first surface of the encapsulant. A second interconnect structure is formed over a second surface of the encapsulant. The first and second interconnect structures are electrically connected to the first and second bodies of the leadframe.

### FIELD OF THE INVENTION

The present invention relates in general to semiconductor devices and, more particularly, to a semiconductor device and method of forming a leadframe as a vertical interconnect structure between stacked semiconductor die in a fan-out wafer level chip scale package (Fo-WLCSP).

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. Back-end manufacturing involves singulating individual die from the finished wafer and packaging the die to provide structural support and environmental isolation.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller die size may be achieved by improvements in the front-end process resulting in die with smaller, higher density active and passive components. Back-end processes may result in semiconductor device packages with a smaller footprint by improvements in electrical interconnection and packaging materials.

FIG. 1 illustrates a conventional Fo-WLCSP 10 with flipchip semiconductor die 12 having bumps 14 formed over contact pads 16 on active surface 18. Conductive through silicon vias (TSV) 20 are formed through semiconductor die 12. Semiconductor die 22 is mounted to semiconductor die 12 and electrically connected to conductive TSV 20 with bumps 23. An encapsulant 24 is deposited over semiconductor die 12 and 22. A build-up interconnect structure 25 is formed over encapsulant 25. Conductive TSV 20 provides vertical interconnect between semiconductor die 12 and semiconductor die 22 and interconnect structure 25. However, conductive TSV 20 involve a time-consuming plating process and are susceptible to void formation.

FIG. 2 illustrates another conventional Fo-WLCSP 26 with flipchip semiconductor die 27 having bumps 28 formed over contact pads 29 on active surface 30. Conductive edge layers 31 are formed over a top surface, side surface, and bottom surface of semiconductor die 27. Semiconductor die 32 is mounted to semiconductor die 27 and electrically connected to conductive edge layer 31 with bumps 33. An encapsulant 34 is deposited over semiconductor die 27 and 32. A build-up interconnect structure 35 is formed over encapsulant 34. Conductive edge layer 31 provides vertical interconnect between semiconductor die 32 and semiconductor die 27 and interconnect structure 35. Conductive edge layer 31 requires edge plating, which is a relatively complicated and expensive process involving lithography, etching, and metal deposition.

FIG. 3 illustrates another conventional Fo-WLCSP 36 with flipchip semiconductor die 37 having bumps 38 formed over contact pads 39 on active surface 40. A conductive layer 41 is formed over a top surface of semiconductor die 37. Bond wires 42 are electrically connected to conductive layer 41. Semiconductor die 43 is mounted to semiconductor die 37 and electrically connected to conductive layer 41 with bumps 44. An encapsulant 45 is deposited over semiconductor die 37 and 43. A build-up interconnect structure 46 is formed over encapsulant 45. Conductive layer 41 and bond wires 42 provide vertical interconnect between semiconductor die 43 and semiconductor die 37 and interconnect structure 46. Conductive layer 41 and bond wires 42 require complicated processes such as wire-bonding and forming a redistribution layer (RDL) on the backside of semiconductor die 37, both of which can be costly and time consuming. In addition, bond wires 42 are susceptible to electrical shorting due to wire-swaying during encapsulation or shorting between wire and bottom surface of semiconductor die 43.

### SUMMARY OF THE INVENTION

A need exists for a simple and cost-effective vertical electrical interconnect structure between stacked semiconductor die. Accordingly, in one embodiment, the present invention is a method of making a semiconductor device comprising the steps of providing a carrier, mounting a plurality of first semiconductor die over the carrier, providing a leadframe having a plurality of conductive leads and bodies extending from the conductive leads, mounting the leadframe to the carrier with the conductive lead disposed over the first semiconductor die and the bodies disposed around the first semiconductor die, mounting a plurality of second semiconductor die over the leadframe, depositing an encapsulant over the first and second semiconductor die, removing the carrier, forming an interconnect structure over the encapsulant, and singulating the semiconductor device to separate the first semiconductor die. The interconnect structure is electrically connected to the bodies of the leadframe.

In another embodiment, the present invention is a method of making a semiconductor device comprising the steps of providing a carrier, mounting a first semiconductor die over the carrier, providing a leadframe having a plurality of conductive leads and bodies extending from the conductive leads, mounting the leadframe to the carrier with the conductive lead disposed over the first semiconductor die and the bodies disposed around the first semiconductor die, depositing an encapsulant over the first semiconductor die, removing the carrier, and forming an interconnect structure over the encapsulant. The interconnect structure is electrically connected to the bodies of the leadframe.

In another embodiment, the present invention is a method of making a semiconductor device comprising the steps of providing a plurality of first semiconductor die, mounting a leadframe having a plurality of conductive leads and first bodies extending from the conductive leads over the first semiconductor die with the conductive lead disposed over the first semiconductor die and the first bodies disposed around the first semiconductor die, depositing a first encapsulant over the first semiconductor die, and forming a first interconnect structure over a first surface of the first encapsulant. The first interconnect structure is electrically connected to the first bodies of the leadframe.

In another embodiment, the present invention is a semiconductor device comprising a first semiconductor die and leadframe having a plurality of conductive leads and first bodies extending from the conductive leads mounted over the first semiconductor die with the conductive lead disposed over the first semiconductor die and the first bodies disposed around the first semiconductor die. An encapsulant is deposited over the first semiconductor die. A first interconnect structure is formed over a first surface of the encapsulant. The first interconnect structure is electrically connected to the first bodies of the leadframe.

### BRIEF DESCRIPTION OF THE DRAWINGS

FIG. 1 shows conventional stacked semiconductor die with vertical interconnect through conductive TSV;

FIG. 2 shows conventional stacked semiconductor die with vertical interconnect through a conductive edge layer;

FIG. 3 shows conventional stacked semiconductor die with vertical interconnect through RDL and bond wires;

FIG. 4 illustrates a PCB with different types of packages mounted to its surface;

FIGS. 5a-5c illustrate further detail of the representative semiconductor packages mounted to the PCB;

FIGS. 6a-6c illustrate a semiconductor wafer with a plurality of semiconductor die separated by saw streets;

FIGS. 7a-7k illustrate a process of forming a leadframe as a vertical interconnect structure between stacked semiconductor die in a Fo-WLCSP;

FIG. 8 illustrates the Fo-WLCSP with a vertical interconnect structure formed with a leadframe between stacked semiconductor die;

FIG. 9 illustrates a conductive lead of the leadframe formed over a central portion of the top semiconductor die;

FIG. 10 illustrates a bottom semiconductor die without bumps;

FIG. 11 illustrates an underfill material deposited under the bottom semiconductor die;

FIG. 12 illustrates a portion of the top semiconductor die removed by backgrinding;

FIG. 13 illustrates an underfill material deposited under the bottom semiconductor die and a portion of the top semiconductor die removed by backgrinding;

FIG. 14 illustrates a heat sink and thermal interface material formed over the top semiconductor die;

FIG. 15 illustrates a shielding layer formed over the top semiconductor die and grounded through conductive TMV;

FIG. 16 illustrates an encapsulant deposited over a back surface of the bottom semiconductor die;

FIG. 17 illustrates a recess formed in the conductive lead under the bump of the top semiconductor die;

FIG. 18 illustrates a protrusion formed over the conductive lead under the bump of the top semiconductor die;

FIG. 19 illustrates a groove formed in the conductive lead around the bump of the top semiconductor die;

FIG. 20 illustrates the conductive pillar of the leadframe exposed from the Fo-WLCSP;

FIG. 21 illustrates a conductive TMV formed through the encapsulant and electrically connected to a build-up interconnect structure formed over the encapsulant;

FIG. 22 illustrates an opposing conductive pillar of the leadframe formed through the encapsulant and connected to an interconnect structure formed over the encapsulant; and

FIG. 23 illustrates the top and bottom semiconductor die inverted within the leadframe.

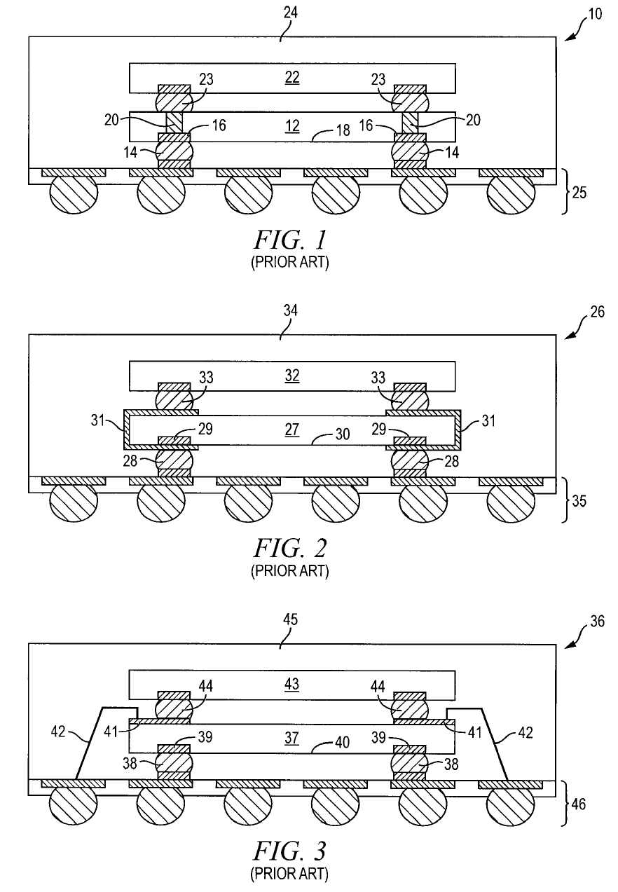

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting tool or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or bond wires. An encapsulant or other molding material is deposited over the package to provide physical support and electrical isolation. The finished package is then inserted into an electrical system and the functionality of the semiconductor device is made available to the other system components.

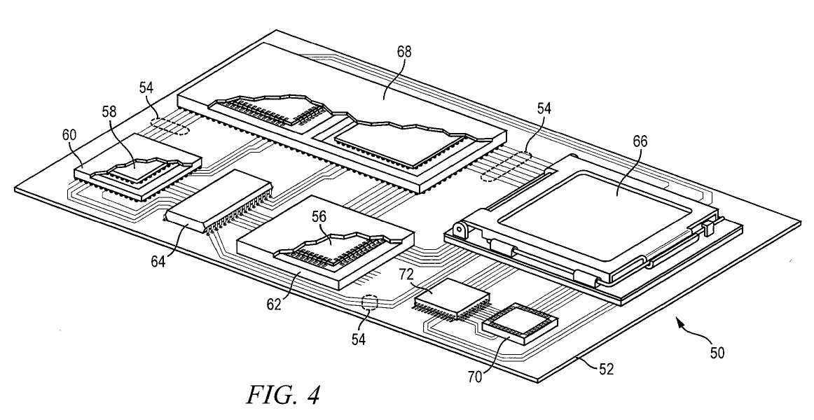

FIG. 4 illustrates electronic device 50 having a chip carrier substrate or printed circuit board (PCB) 52 with a plurality of semiconductor packages mounted on its surface. Electronic device 50 may have one type of semiconductor package, or multiple types of semiconductor packages, depending on the application. The different types of semiconductor packages are shown in FIG. 4 for purposes of illustration.

Electronic device 50 may be a stand-alone system that uses the semiconductor packages to perform one or more electrical functions. Alternatively, electronic device 50 may be a subcomponent of a larger system. For example, electronic device 50 may be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. The miniaturization and the weight reduction are essential for these products to be accepted by the market. The distance between semiconductor devices must be decreased to achieve higher density.

In FIG. 4, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including wire bond package 56 and flip chip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using cheaper components and a streamlined manufacturing process. The resulting devices are less likely to fail and less expensive to manufacture resulting in a lower cost for consumers.

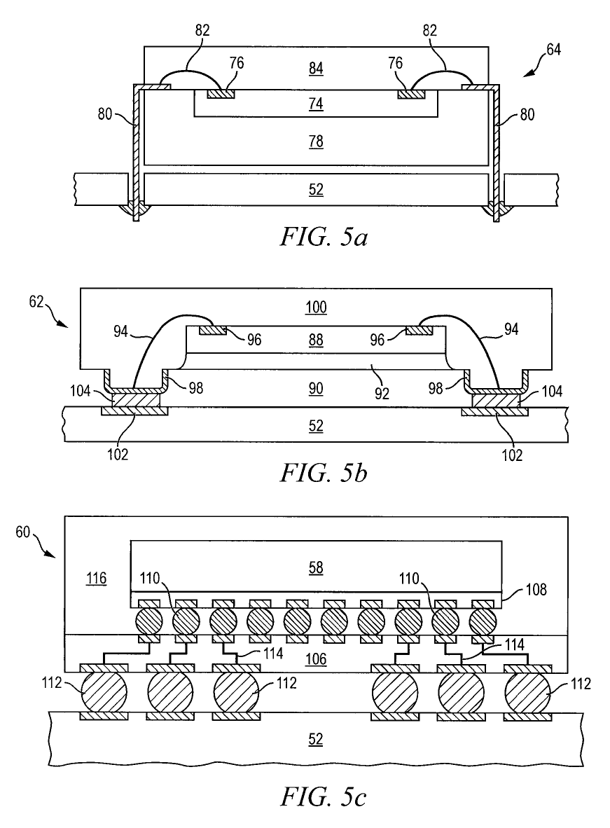

FIGS. 5a-5c show exemplary semiconductor packages. FIG. 5a illustrates further detail of DIP 64 mounted on PCB 52. Semiconductor die 74 includes an active region containing analog or digital circuits implemented as active devices, passive devices, conductive layers, and dielectric layers formed within the die and are electrically interconnected according to the electrical design of the die. For example, the circuit may include one or more transistors, diodes, inductors, capacitors, resistors, and other circuit elements formed within the active region of semiconductor die 74. Contact pads 76 are one or more layers of conductive material, such as aluminum (Al), copper (Cu), tin (Sn), nickel (Ni), gold (Au), or silver (Ag), and are electrically connected to the circuit elements formed within semiconductor die 74. During assembly of DIP 64, semiconductor die 74 is mounted to an intermediate carrier 78 using a gold-silicon eutectic layer or adhesive material such as thermal epoxy or epoxy resin. The package body includes an insulative packaging material such as polymer or ceramic. Conductor leads 80 and wire bonds 82 provide electrical interconnect between semiconductor die 74 and PCB 52. Encapsulant 84 is deposited over the package for environmental protection by preventing moisture and particles from entering the package and contaminating die 74 or wire bonds 82.

FIG. 5b illustrates further detail of BCC 62 mounted on PCB 52. Semiconductor die 88 is mounted over carrier 90 using an underfill or epoxy-resin adhesive material 92. Wire bonds 94 provide first level packaging interconnect between contact pads 96 and 98. Molding compound or encapsulant 100 is deposited over semiconductor die 88 and wire bonds 94 to provide physical support and electrical isolation for the device. Contact pads 102 are formed over a surface of PCB 52 using a suitable metal deposition process such as electrolytic plating or electroless plating to prevent oxidation. Contact pads 102 are electrically connected to one or more conductive signal traces 54 in PCB 52. Bumps 104 are formed between contact pads 98 of BCC 62 and contact pads 102 of PCB 52.

In FIG. 5c, semiconductor die 58 is mounted face down to intermediate carrier 106 with a flip chip style first level packaging. Active region 108 of semiconductor die 58 contains analog or digital circuits implemented as active devices, passive devices, conductive layers, and dielectric layers formed according to the electrical design of the die. For example, the circuit may include one or more transistors, diodes, inductors, capacitors, resistors, and other circuit elements within active region 108. Semiconductor die 58 is electrically and mechanically connected to carrier 106 through bumps 110.

BGA 60 is electrically and mechanically connected to PCB 52 with a BGA style second level packaging using bumps 112. Semiconductor die 58 is electrically connected to conductive signal traces 54 in PCB 52 through bumps 110, signal lines 114, and bumps 112. A molding compound or encapsulant 116 is deposited over semiconductor die 58 and carrier 106 to provide physical support and electrical isolation for the device. The flip chip semiconductor device provides a short electrical conduction path from the active devices on semiconductor die 58 to conduction tracks on PCB 52 in order to reduce signal propagation distance, lower capacitance, and improve overall circuit performance. In another embodiment, the semiconductor die 58 can be mechanically and electrically connected directly to PCB 52 using flip chip style first level packaging without intermediate carrier 106.

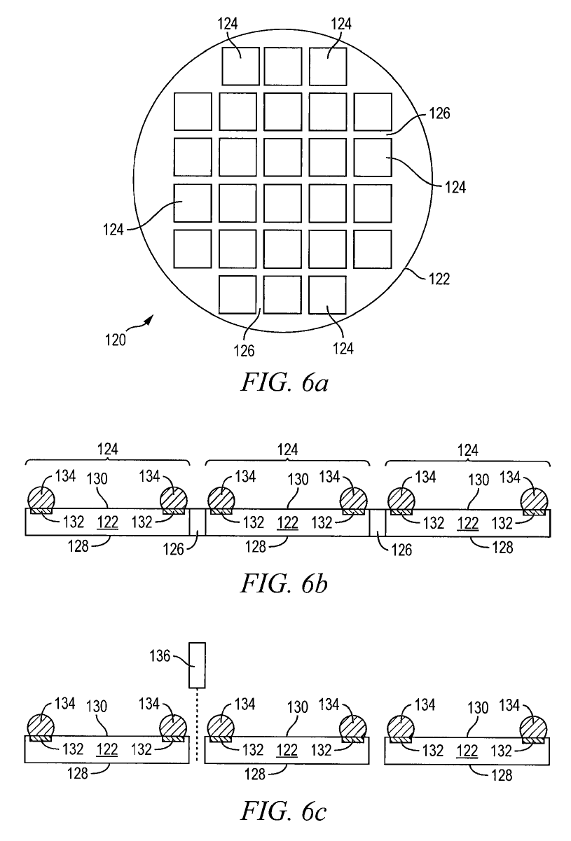

FIG. 6a shows a semiconductor wafer 120 with a base substrate material 122, such as silicon, germanium, gallium arsenide, indium phosphide, or silicon carbide, for structural support. A plurality of semiconductor die or components 124 is formed on wafer 120 separated by saw streets 126, as described above.

FIG. 6b shows a cross-sectional view of a portion of semiconductor wafer 120. Each semiconductor die 124 has a back surface 128 and an active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPD), such as inductors, capacitors, and resistors, for RF signal processing.

An electrically conductive layer 132 is formed over active surface 130 using PVD, CVD, electrolytic plating, electroless plating process, or other suitable metal deposition process. Conductive layer 132 can be one or more layers of Al, Cu, Sn, Ni, Au, Ag, or other suitable electrically conductive material. Conductive layer 132 operates as contact pads electrically connected to the circuits on active surface 130. In one embodiment, semiconductor die 124 is a flipchip type semiconductor die.

An electrically conductive bump material is deposited over contact pads 132 while in wafer form using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to contact pads 132 using a suitable attachment or bonding process. In one embodiment, the bump material is reflowed by heating the material above its melting point to form spherical or rounded balls or bumps 134. In some applications, bumps 134 are reflowed a second time to improve electrical contact to contact pads 132. The bumps can also be compression bonded to contact pads 132.

In FIG. 6c, semiconductor wafer 120 is singulated through saw street 126 using saw blade or laser cutting tool 136 into individual semiconductor die 124. Each semiconductor die 124 has bumps 134 formed over contact pads 132.

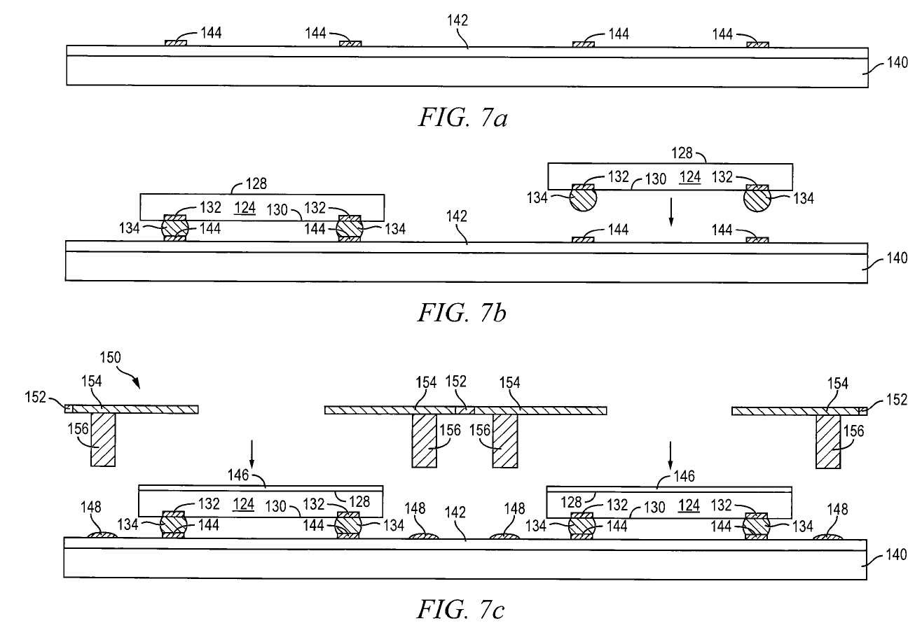

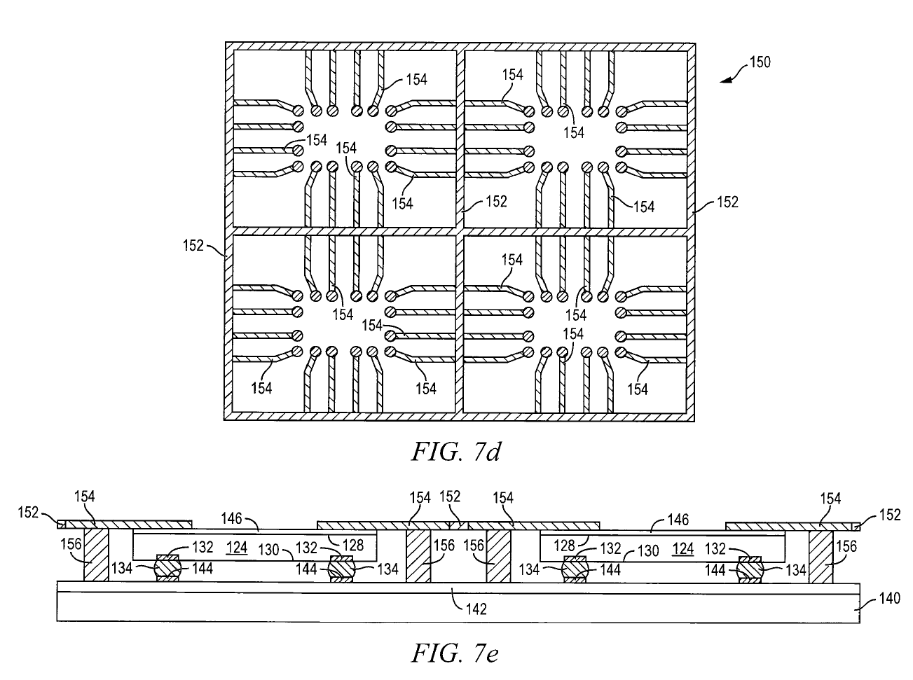

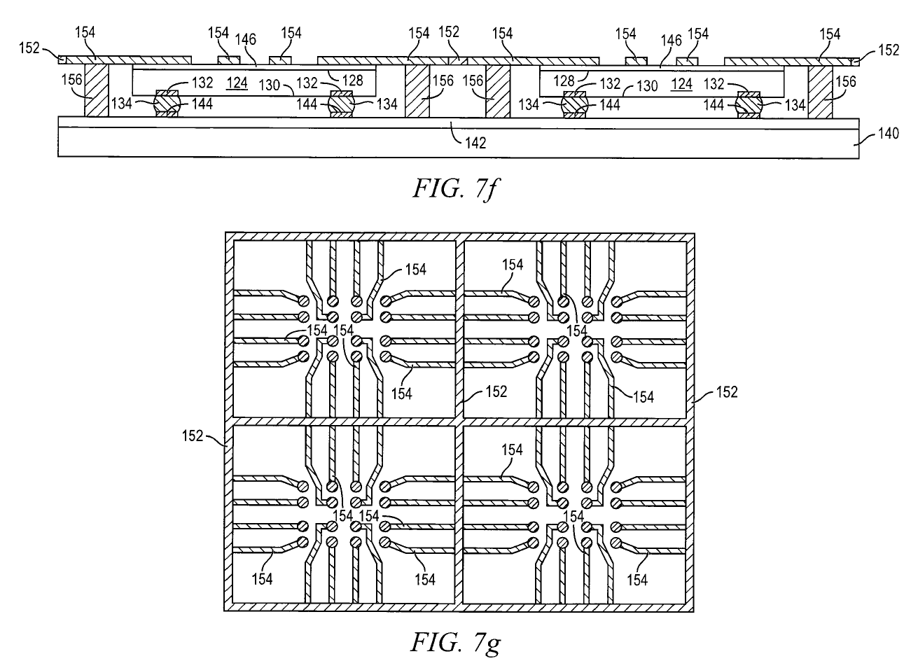

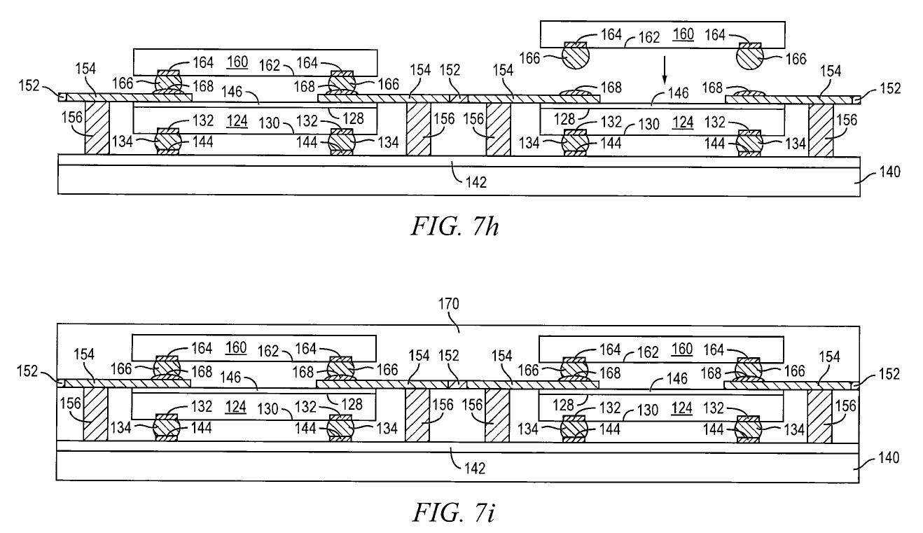

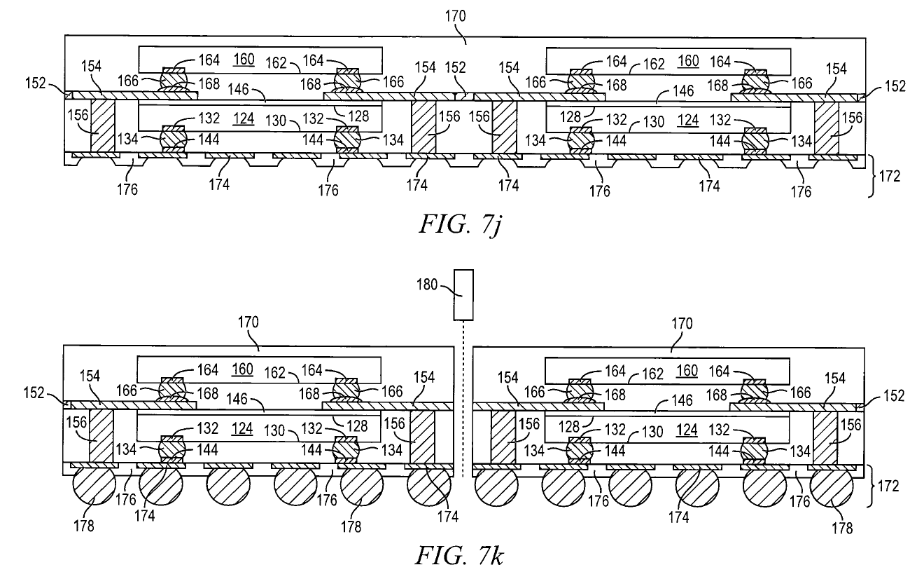

FIGS. 7a-7k illustrate, in relation to FIGS. 4 and 5a-5c, a process of forming a leadframe as a vertical interconnect structure between stacked semiconductor die in a Fo-WLCSP. In FIG. 7a, a substrate or carrier 140 contains temporary or sacrificial base material such as silicon, polymer, polymer composite, metal, ceramic, glass, glass epoxy, beryllium oxide, or other suitable low-cost, rigid material for structural support. An optional interface layer or double-sided tape 142 can be formed over carrier 140 as a temporary adhesive bonding film or etch-stop layer.

An electrically conductive layer 144 is formed over interface layer 142 of carrier 140 using PVD, CVD, electrolytic plating, electroless plating process, or other suitable metal deposition process. Conductive layer 144 can be one or more layers of Al, Cu, Sn, Ni, Au, Ag, or other suitable electrically conductive material. Conductive layer 144 operates as contact pads for receiving bumps 134 of semiconductor die 124.

In FIG. 7b, semiconductor die 124 from FIGS. 6a-6c are mounted to carrier 140 using a pick and place operation with active surface 130 oriented toward carrier 140 and bumps 134 aligned to contact pads 144. Contact pads 144 can be wettable pads to enhance adhesion with bumps 134. An adhesive layer 146 is deposited over back surface 128 of semiconductor die 124 while in wafer form or after placement of the semiconductor die on carrier 140. In addition, adhesive beads 148 can be deposited over carrier 140.

FIG. 7c shows a wafer-form leadframe 150 having tie bars 152 formed around a perimeter of the leadframe with integrated conductive leads or fingers 154 arranged in rows and a plurality of bodies 156 extending from the conductive leads. FIG. 7d shows a top view of leadframe 150 with tie bars 152 and conductive leads 154 arranged in rows around semiconductor die 124. In one embodiment, leadframe 150 is an un-singulated pre-formed laminated substrate made with leadframe manufacturing techniques, such as stamping. Leadframe 150 can be gold, silver, nickel, platinum, copper, copper alloys (including one or more elements of nickel, iron, zinc, tin, chromium, silver, and phosphorous), or other suitable materials. Tie bars 152 are removed in a subsequent manufacturing step, e.g., before electrical testing.

Leading with bodies 156, leadframe 150 is aligned over interface layer 142 and carrier 140 to position bodies 156 around a perimeter of semiconductor die 124. FIG. 7e shows leadframe 150 mounted over semiconductor die 124 to carrier 140 and secured in place with conductive leads 154 adhering to adhesive layer 146 over back surface 128 of semiconductor die 124 and bodies 156 adhering to adhesive beads 148 over interface layer 142 of carrier 140. Accordingly, conductive leads 154 are disposed over a portion of back surface 128 of semiconductor die 124.

In another embodiment, as shown in FIG. 7f, conductive leads 154 are uniformly distributed over back surface 128 of semiconductor die 124 and secured to the back surface with adhesive layer 146. FIG. 7g shows a top view of leadframe 150 with tie bars 152 and conductive leads 154 uniformly distributed over back surface 128 of semiconductor die 124.

FIG. 7h shows semiconductor die 160, similar to FIGS. 6a-6c, having an active surface 162 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 162 to implement analog circuits or digital circuits, such as DSP, ASIC, memory, or other signal processing circuit. Semiconductor die 160 may also contain IPDs, such as inductors, capacitors, and resistors, for RF signal processing. In one embodiment, semiconductor die 160 is a flipchip type semiconductor die. Contact pads 164 are formed on active surface 162 and electrically connected to the circuits on the active surface. A plurality of bumps 166 is formed over contact pads 164.

Semiconductor die 160 are mounted to a top surface of conductive leads 154, opposite semiconductor die 124, using a pick and place operation with active surface 162 oriented toward carrier 140 and bumps 166 aligned to the conductive leads. Bumps 166 are reflowed to metallurgically and electrically connect semiconductor die 160 to conductive leads 154. An optional flux material 168 can be deposited over conductive leads 154 to aid the reflow process.

In FIG. 7i, an encapsulant or molding compound 170 is deposited over carrier 140 and around semiconductor die 124 and 160 and leadframe 150 using a paste printing, compressive molding, transfer molding, liquid encapsulant molding, vacuum lamination, spin coating, or other suitable applicator. Encapsulant 170 can be polymer composite material, such as epoxy resin with filler, epoxy acrylate with filler, or polymer with proper filler. Encapsulant 170 is non-conductive and environmentally protects the semiconductor device from external elements and contaminants.

In FIG. 7j, temporary carrier 140 and interface layer 142 are removed by chemical etching, mechanical peel-off, CMP, mechanical grinding, thermal bake, UV light, laser scanning, or wet stripping. A build-up interconnect structure 172 is formed over bodies 156 and encapsulant 170. The build-up interconnect structure 172 includes an electrically conductive layer or redistribution layer (RDL) 174 formed using a patterning and metal deposition process such as sputtering, electrolytic plating, and electroless plating. Conductive layer 174 can be one or more layers of Al, Cu, Sn, Ni, Au, Ag, or other suitable electrically conductive material. One portion of conductive layer 174 is electrically connected to contact pads 144. Another portion of conductive layer 174 is electrically connected to bodies 156, which operate as z-direction vertical interconnect conductive pillars through encapsulant 170. Other portions of conductive layer 174 can be electrically common or electrically isolated depending on the design and function of semiconductor die 124 and 160.

An insulating or passivation layer 176 is formed around conductive layer 174 for electrical isolation using PVD, CVD, printing, spin coating, spray coating, sintering or thermal oxidation. The insulating layer 176 contains one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. A portion of insulating layer 176 can be removed by an etching process to expose conductive layer 174 for additional electrical interconnect.

In FIG. 7k, an electrically conductive bump material is deposited over build-up interconnect structure 172 and electrically connected to the exposed portion of conductive layer 174 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 174 using a suitable attachment or bonding process. In one embodiment, the bump material is reflowed by heating the material above its melting point to form spherical balls or bumps 178. In some applications, bumps 178 are reflowed a second time to improve electrical contact to conductive layer 174. An under bump metallization (UBM) can be formed under bumps 178. The bumps can also be compression bonded to conductive layer 174. Bumps 178 represent one type of interconnect structure that can be formed over conductive layer 174. The interconnect structure can also use stud bump, micro bump, or other electrical interconnect.

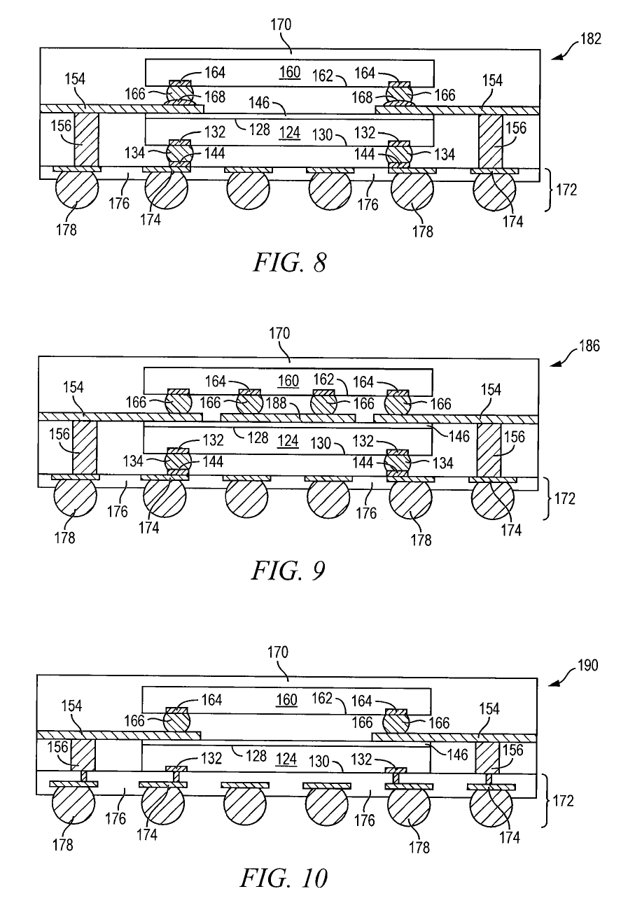

Semiconductor die 124 and 160 are singulated through tie bars 152 of leadframe 150, encapsulant 170, and interconnect structure 172 with saw blade or laser cutting tool 180 into individual Fo-WLCSP 182. FIG. 8 shows Fo-WLCSP 182 after singulation. Semiconductor die 124 is electrically connected through contact pads 132 and build-up interconnect structure 172 to leadframe 150. Likewise, semiconductor die 160 is electrically connected through contact pads 166 and leadframe 150 to build-up interconnect structure 172. Leadframe 150 provides a simple and cost effective structure for semiconductor die stacking above and below the leadframe. In particular, conductive leads 154 overhang semiconductor die 124 during assembly. Semiconductor die 124 and 160 can be same size die, such as memory devices. Leadframe 150 provides a balanced structure and reduces warpage. In addition, leadframe 150 provides RDL electrical interconnect through conductive leads 154 between semiconductor die 124 and 160 and z-direction vertical electrical interconnect with conductive pillars 156 around a perimeter of semiconductor die 124.

FIG. 9 shows an embodiment of Fo-WLCSP 186, similar to FIG. 8, with conductive lead 188 of leadframe 150 disposed over a central area of back surface 128 of semiconductor die 124. Conductive lead 188 provides additional electrical interconnect to bumps 166 of semiconductor die 160.

FIG. 10 shows an embodiment of Fo-WLCSP 190, similar to FIG. 8, without bumps 134. Contact pads 132 of semiconductor die 124 are directly connected to conductive layer 174 of build-up interconnect structure 172.

FIG. 11 shows an embodiment of Fo-WLCSP 194, similar to FIG. 8, with an underfill material 196, such as epoxy resin, deposited under semiconductor die 124 prior to mounting leadframe 150 in FIG. 7c. A portion of back surface 128 is removed by a grinding operation to reduce the thickness of semiconductor die 124, after depositing underfill material 196. Adhesive layer 146 is deposited over the back surface of semiconductor die 124 after the backgrinding operation.

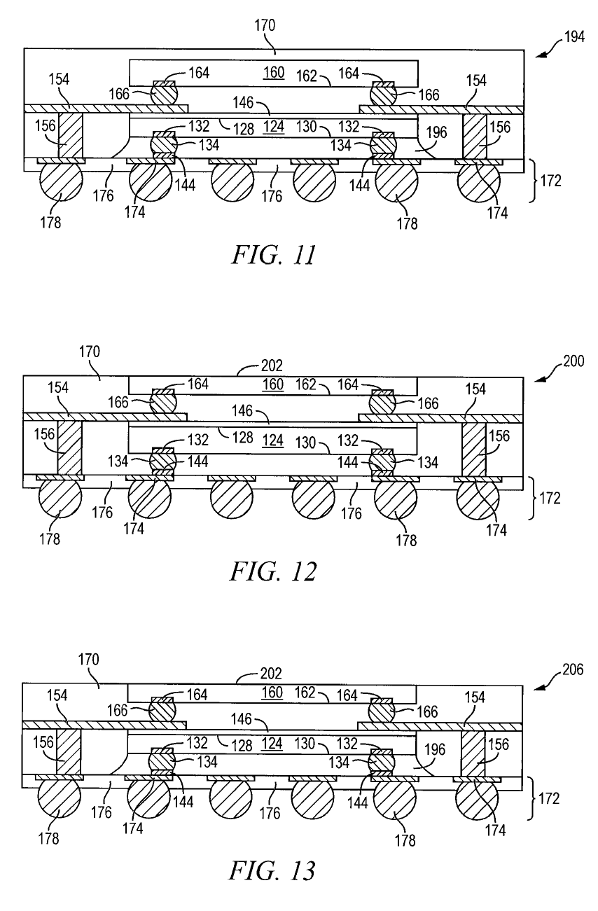

FIG. 12 shows an embodiment of Fo-WLCSP 200, similar to FIG. 8, with a portion of back surface 202 of semiconductor die 160 removed by a grinding operation to reduce the thickness of the semiconductor die. Back surface 202 is substantially coplanar with encapsulant 170 after the backgrinding operation.

FIG. 13 shows an embodiment of Fo-WLCSP 206, similar to FIGS. 11 and 12, with an underfill material 196, such as epoxy resin, deposited under semiconductor die 124 prior to mounting leadframe 150 in FIG. 7c. A portion of back surface 128 is removed by a grinding operation to reduce the thickness of semiconductor die 124, after depositing underfill material 196. Adhesive layer 146 is deposited over the back surface of semiconductor die 124 after the backgrinding operation. In addition, a portion of back surface 202 of semiconductor die 160 is removed by a grinding operation to reduce the thickness of the semiconductor die. Back surface 202 is substantially coplanar with encapsulant 170 after the backgrinding operation.

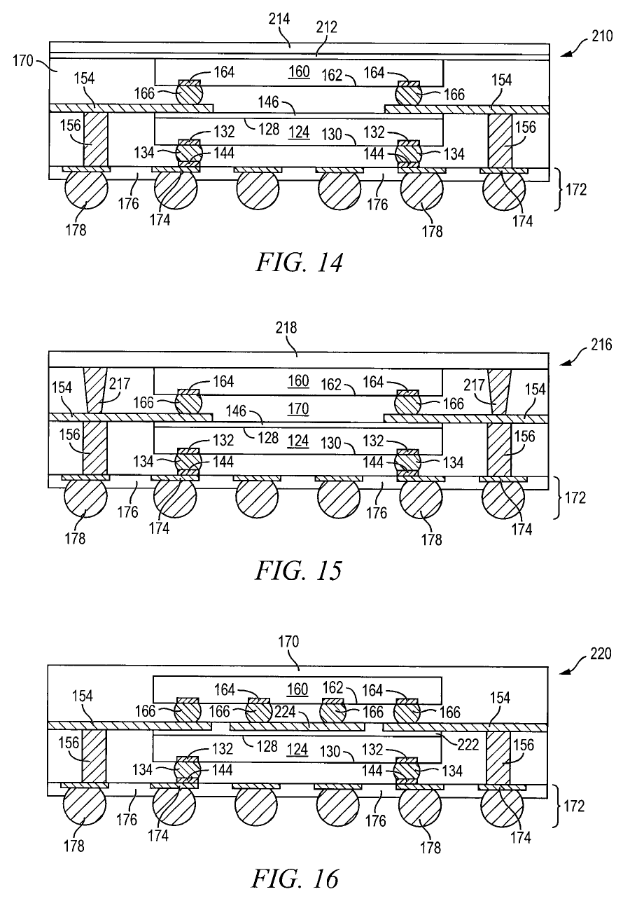

FIG. 14 shows an embodiment of Fo-WLCSP 210, similar to FIG. 12, with a thermal interface material (TIM) 212 deposited over back surface 202 of semiconductor die 160 and encapsulant 170 to aid with heat transfer away from the Fo-WLCSP. TIM 212 can be aluminum oxide, zinc oxide, boron nitride, or pulverized silver. A heat sink 214 is mounted over TIM 210. Heat sink 214 can be Al, Cu, or another material with high thermal conductivity to provide heat dissipation for semiconductor die 124 and 160. Heat sink 214 also provides a protective surface for the backside of semiconductor die 160, as well as a stiffening function to reduce warpage.

FIG. 15 shows an embodiment of Fo-WLCSP 216, similar to FIG. 12, with a plurality of vias formed through encapsulant 170 using laser drilling or etching process, such as deep reactive ion etching (DRIE). The vias are filled with Al, Cu, Sn, Ni, Au, Ag, titanium (Ti), W, poly-silicon, or other suitable electrically conductive material using PVD, CVD, electrolytic plating, electroless plating process, or other suitable metal deposition process to form conductive through mold vias (TMV) 217. Conductive TMV 217 are electrically connected to conductive pillars 156.

An electrically conductive shielding layer 218 is deposited over back surface 202 of semiconductor die 160 and conductive TMV 217 to reduce electromagnetic interference (EMI) and radio frequency interference (RFI). Shielding layer 218 can be Cu, Al, soft-magnetic materials such as ferrite or carbonyl iron, stainless steel, nickel silver, low-carbon steel, silicon-iron steel, foil, epoxy, conductive resin, and other metals and composites capable of blocking or absorbing EMI, RFI, and other inter-device interference. Alternatively, shielding layer 218 can be a dielectric material such as carbon-black or aluminum flake to reduce the effects of EMI and RFI. Shielding layer 218 is grounded through conductive TMV 217, conductive leads 154, conductive pillars 156, and interconnect structure 172. Alternatively, shielding layer 218 extends along a side surface of Fo-WLCSP 216 to conductive leads 154 for grounding through conductive pillars 156 and interconnect structure 172.

FIG. 16 shows an embodiment of Fo-WLCSP 220, similar to FIG. 8, with an encapsulant or molding compound 222 deposited over back surface 128 of semiconductor die 124 using a paste printing, compressive molding, transfer molding, liquid encapsulant molding, vacuum lamination, spin coating, or other suitable applicator. Encapsulant 222 is deposited prior to mounting leadframe 150 in FIG. 7c. Encapsulant 222 can be polymer composite material, such as epoxy resin with filler, epoxy acrylate with filler, or polymer with proper filler. Leadframe 150 is mounted to encapsulant 222 which secures the leadframe to semiconductor die 124. Leadframe 150 includes a conductive lead 224 disposed over a central area of back surface 128 of semiconductor die 124. Conductive lead 224 provides additional electrical interconnect to bumps 166 of semiconductor die 160.

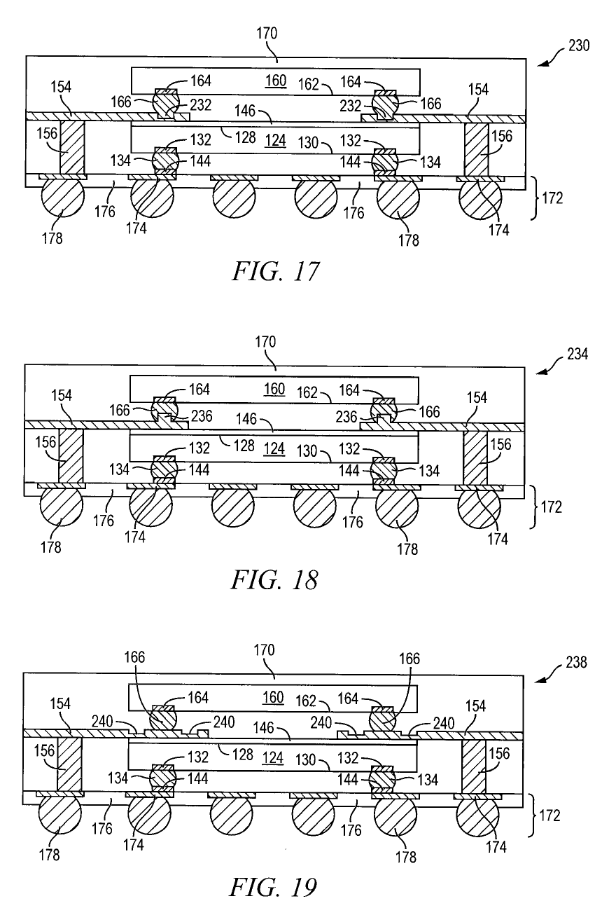

FIG. 17 shows an embodiment of Fo-WLCSP 230, similar to FIG. 8, with recesses or notches 232 formed in conductive leads 154 under bumps 166 by an etching process. Recesses 232 provide alignment for bumps 166 when mounting semiconductor die 160.

FIG. 18 shows an embodiment of Fo-WLCSP 234, similar to FIG. 8, with protrusions 236 formed over conductive leads 154 under bumps 166. Protrusions 236 improve electrical connection to bumps 166 when mounting semiconductor die 160.

FIG. 19 shows an embodiment of Fo-WLCSP 238, similar to FIG. 8, with grooves or slots 240 formed in conductive leads 154 around bumps 166. Grooves 240 operate as solder resist during the reflow of bumps 166.

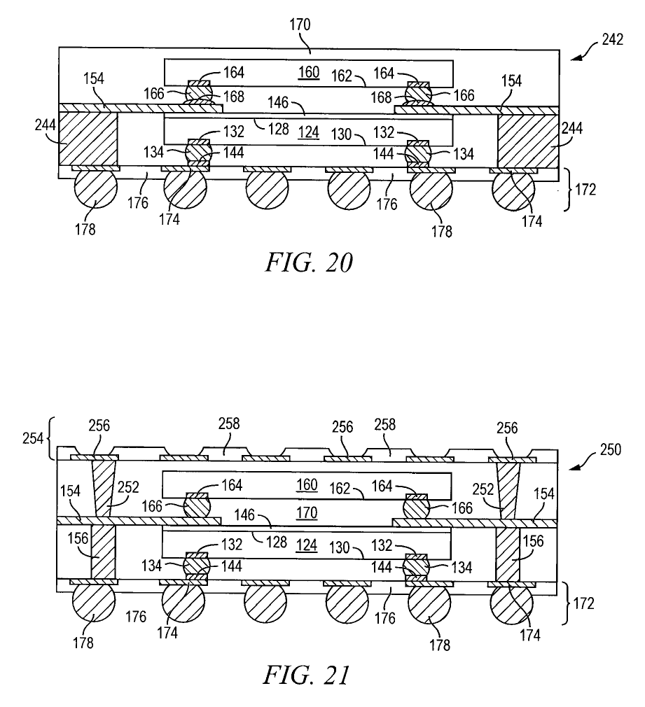

FIG. 20 shows an embodiment of Fo-WLCSP 242, similar to FIG. 8, with bodies 244 extending from conductive leads 154 of leadframe 150, similar to bodies 156. Bodies 244 operate as z-direction vertical interconnect conductive pillars through encapsulant 170 and are exposed from a side surface of Fo-WLCSP 242.

FIG. 21 shows an embodiment of Fo-WLCSP 250, similar to FIG. 8, with a plurality of vias formed through encapsulant 170 using laser drilling or etching process, such as DRIE. The vias are filled with Al, Cu, Sn, Ni, Au, Ag, Ti, W, poly-silicon, or other suitable electrically conductive material using PVD, CVD, electrolytic plating, electroless plating process, or other suitable metal deposition process to form conductive TMV 252. Conductive TMV 252 are electrically connected to conductive leads 154.

A build-up interconnect structure 254 is formed over encapsulant 170 and conductive TMV 252. The build-up interconnect structure 254 includes an electrically conductive layer or RDL 256 formed using a patterning and metal deposition process such as sputtering, electrolytic plating, and electroless plating. Conductive layer 256 can be one or more layers of Al, Cu, Sn, Ni, Au, Ag, or other suitable electrically conductive material. One portion of conductive layer 256 is electrically connected to conductive TMV 252. Other portions of conductive layer 256 can be electrically common or electrically isolated depending on the design and function of semiconductor die 124 and 160.

An insulating or passivation layer 258 is formed over conductive layer 254 for electrical isolation using PVD, CVD, printing, spin coating, spray coating, sintering or thermal oxidation. The insulating layer 258 contains one or more layers of SiO2, Si3N4, SiON, Ta2O5, Al2O3, or other material having similar insulating and structural properties. A portion of insulating layer 258 can be removed by an etching process to expose conductive layer 254 for additional electrical interconnect.

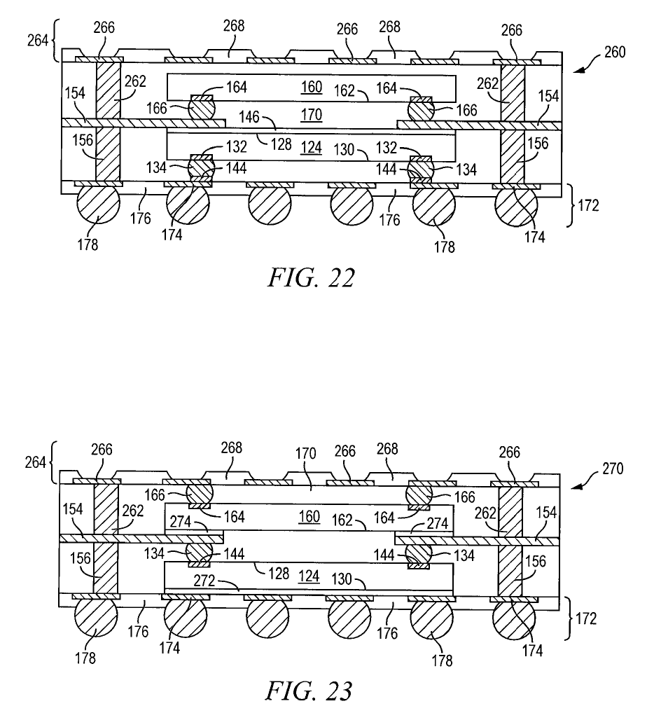

FIG. 22 shows an embodiment of Fo-WLCSP 260, similar to FIG. 8, with bodies 262 extending from a surface of conductive leads 154 of leadframe 150 opposite bodies 156. Bodies 262 operate as z-direction vertical interconnect conductive pillars, similar to bodies 156, through encapsulant 170.

A build-up interconnect structure 264 is formed over encapsulant 170 and conductive pillars 262. The build-up interconnect structure 264 includes an electrically conductive layer or RDL 266 formed using a patterning and metal deposition process such as sputtering, electrolytic plating, and electroless plating. Conductive layer 266 can be one or more layers of Al, Cu, Sn, Ni, Au, Ag, or other suitable electrically conductive material. One portion of conductive layer 266 is electrically connected to conductive pillars 262. Other portions of conductive layer 266 can be electrically common or electrically isolated depending on the design and function of semiconductor die 124 and 160.

An insulating or passivation layer 268 is formed over conductive layer 264 for electrical isolation using PVD, CVD, printing, spin coating, spray coating, sintering or thermal oxidation. The insulating layer 268 contains one or more layers of SiO2, Si3N4, SiON, Ta2O5, Al2O3, or other material having similar insulating and structural properties. A portion of insulating layer 268 can be removed by an etching process to expose conductive layer 264 for additional electrical interconnect.

FIG. 23 shows an embodiment of Fo-WLCSP 270, similar to FIG. 22, with semiconductor die 124 and 160 inverted within leadframe 150. That is, bumps 134 are electrically connected to conductive leads 154 and bumps 166 are electrically connected to conductive layer 266. Semiconductor die 124 is mounted to interconnect structure 172 with adhesive layer 272. Semiconductor die 160 is mounted to conductive leads 154 with adhesive layer 274.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of manufacturing a semiconductor device, comprising:
providing a carrier;
mounting a plurality of first semiconductor die over the carrier;
providing a leadframe having a plurality of conductive leads and bodies extending from the conductive leads;
mounting the leadframe to the carrier with the conductive lead disposed over the first semiconductor die and the bodies disposed around the first semiconductor die;
mounting a plurality of second semiconductor die over the leadframe;
depositing an encapsulant over the first and second semiconductor die;
removing the carrier;
forming an interconnect structure over the encapsulant, the interconnect structure being electrically connected to the bodies of the leadframe; and
singulating the semiconductor device to separate the first semiconductor die.

2. The method of claim 1, further including depositing an adhesive layer between the first semiconductor die and conductive leads.

3. The method of claim 1, wherein the second semiconductor die is electrically connected to the conductive leads.

4. The method of claim 1, further including forming a recess or groove in the conductive leads.

5. The method of claim 1, further including forming a protrusion over the conductive leads.

6. The method of claim 1, further including forming a heat sink over the second semiconductor die.

7. The method of claim 1, further including forming a shielding layer over the second semiconductor die.

8. A method of manufacturing a semiconductor device, comprising:
providing a carrier;
mounting a first semiconductor die over the carrier;
providing a leadframe having a plurality of conductive leads and bodies extending from the conductive leads;
mounting the leadframe to the carrier with the conductive lead disposed over the first semiconductor die and the bodies disposed around the first semiconductor die;
depositing an encapsulant over the first semiconductor die;
removing the carrier; and
forming an interconnect structure over the encapsulant, the interconnect structure being electrically connected to the bodies of the leadframe.

9. The method of claim 8, further including:
mounting a second semiconductor die over the leadframe; and
depositing the encapsulant over the first and second semiconductor die.

10. The method of claim 9, wherein the second semiconductor die is electrically connected to the conductive leads.

11. The method of claim 8, further including depositing an adhesive layer between the first semiconductor die and conductive leads.

12. The method of claim 1, further including removing a portion of a back surface of the first semiconductor die or second semiconductor die.

13. The method of claim 1, further including depositing an underfill material under the first semiconductor die.

14. A method of manufacturing a semiconductor device, comprising:
providing a plurality of first semiconductor die;
mounting a leadframe having a plurality of conductive leads and first bodies extending from the conductive leads over the first semiconductor die with the conductive lead disposed over the first semiconductor die and the first bodies disposed around the first semiconductor die;
depositing a first encapsulant over the first semiconductor die; and
forming a first interconnect structure over a first surface of the first encapsulant, the first interconnect structure being electrically connected to the first bodies of the leadframe.

15. The method of claim 14, further including:
mounting a second semiconductor die over the leadframe; and
depositing the first encapsulant over the first and second semiconductor die.

16. The method of claim 14, wherein the leadframe includes second bodies extending from the conductive leads opposite the first bodies.

17. The method of claim 16, further including forming a second interconnect structure over a second surface of the first encapsulant opposite the first surface of the first encapsulant, the second interconnect structure being electrically connected to the second bodies of the leadframe.

18. The method of claim 17, further including forming a conductive via through the first encapsulant between the conductive leads and the second interconnect structure.

19. The method of claim 14, further including forming a second encapsulant over the first semiconductor die.

20. The method of claim 14, wherein the first bodies are exposed from the semiconductor device.

21. A semiconductor device, comprising:
a first semiconductor die;
a leadframe having a plurality of conductive leads and first bodies extending from the conductive leads mounted over the first semiconductor die with the conductive lead disposed over the first semiconductor die and the first bodies disposed around the first semiconductor die;
an encapsulant deposited over the first semiconductor die; and
a first interconnect structure formed over a first surface of the encapsulant, the first interconnect structure being electrically connected to the first bodies of the leadframe.

22. The semiconductor device of claim 21, further including a second semiconductor die mounted over the leadframe.

23. The semiconductor device of claim 21, wherein the leadframe includes second bodies extending from the conductive leads opposite the first bodies.

24. The semiconductor device of claim 23, further including a second interconnect structure formed over a second surface of the encapsulant opposite the first surface of the encapsulant, the second interconnect structure being electrically connected to the second bodies of the leadframe.

25. The semiconductor device of claim 24, further including a conductive via through the encapsulant between the conductive leads and the second interconnect structure.
